(19) United States
(12) Patent Application Publication
(10) Pub. No.: US 2006/0097402 A1
(43) Pub. Date: May 11, 2006

(54) Semiconductor device having flip-chip package and method for fabricating the same

(75) Inventors: Han-Ping Pu, Taipei Hsien (TW); Chien-Ping Huang, Hsinchu Hsein (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/267,707

(22) Filed: Nov. 3, 2005

(30) Foreign Application Priority Data
Nov. 8, 2004 (TW) 093133969

(51) Int. Cl. H01L 23/52; H01L 23/48

(52) U.S. Cl. 257/777; 257/778; 257/782; 257/783; 257/784

(57) ABSTRACT

A semiconductor device having a flip-chip package and a method for fabricating the same are provided. A flip-chip package after being tested to be functionally workable is mounted on a carrier and is electrically connected to the carrier by a plurality of first conductive elements, the flip-chip package having a first chip mounted on a substrate in a flip-chip manner. At least a second chip is mounted on the flip-chip package and is electrically connected to the carrier by a plurality of second conductive elements. An encapsulant is formed on the carrier for encapsulating the flip-chip package and the second chip. A plurality of solder balls are implanted on a bottom surface of the carrier, such that the first and second chips can be electrically connected to an external device via the solder balls. The above arrangement can effectively improve the yield of a fabricated product and reduce packaging costs.

### FIELD OF THE INVENTION

The present invention relates to ball grid array (BGA) semiconductor devices and methods for fabricating the same, and more particularly, to a multi-chip BGA semiconductor device and a method for fabricating the semiconductor device.

### BACKGROUND OF THE INVENTION

Besides profile miniaturization, a present electronic product is required to have multiple functions and a high operation speed, and such requirements are usually satisfied by incorporating a highly integrated chip in the electronic product. The high integration of the chip increases the number of input/output (I/O) connections on the chip used for electrically connecting the chip to a chip carrier. A conventional method uses bonding wires such as gold wires to electrically connect the chip to the chip carrier, which is not suitable as being limited by trace routability. Accordingly, a flip-chip method using a plurality of array-arranged solder bumps formed on an active surface of the chip is employed for the electrical connection between the highly integrated chip and the chip carrier. As a pitch between the adjacent solder bumps generally ranges from 150 to 250 μm and is quite small, a build-up substrate must be used as the chip carrier to provide corresponding bump pads for bonding the solder bumps on the chip, which however increases fabrication costs as the build-up substrate is expensive. Further due to the small pitch between the adjacent solder bumps, the solder bumps may easily become bridged during a process of reflowing the solder bumps to the build-up substrate. The bridging effect of the solder bumps lead to short circuit, thereby degrading the yield of a fabricated flip-chip semiconductor package.

Although the flip-chip semiconductor package is suitable for incorporating the highly integrated chip, it is still not able to provide satisfactory performance for an advanced electronic product. A solution is to stack another chip on the flip chip as there is no additional area for accommodating more chips on the substrate of the semiconductor package within the limited space in the electronic product. U.S. Pat. No. 5,815,372 discloses a semiconductor package with such stacked chips. As shown in FIG. 10, the semiconductor package 1′ is fabricated by the steps comprising mounting a first chip 10′ on a build-up substrate 12′ via a plurality of solder bumps 11′ using a flip-chip method; performing an underfilling process to fill an resin material 13′ between the first chip 10′ and the substrate 12′, such that the solder bumps 11′ are completely encapsulated by the resin material 13′; mounting a second chip 14′ on the first chip 10′ and electrically connecting the second chip 14′ to bond pads 120′ of the substrate 12′ via a plurality of gold wires 15′, the bond pads 120′ being located at an area outside the area applied with the resin material 13′; forming an encapsulant 16′ on the substrate 12′ to encapsulate the first chip 10′, the second chip 14′ and the gold wires 15′; and finally, implanting a plurality of array-arranged solder balls 17′ on a bottom surface of the substrate 12′.

The foregoing semiconductor package with the stacked chips may incorporate two or more chips therein to provide satisfactory performance for the electronic product without having to increase the area of the substrate. However, it is still inherent with the following significant drawbacks.

The build-up substrate 12′ used in the semiconductor package 1′ must have a large area to accommodate both the solder bumps 11′ for electrically connecting the first chip 10′ to the substrate 12′ and the gold wires 15′ for electrically connecting the second chip 14′ to the substrate 12′. As the build-up substrate is expensive, the use of a build-up substrate with a large area increases fabrication costs.

The semiconductor package 1′ can only be tested after being packaged. Thus, after the first chip 10′ is mounted on the substrate 12′ using the flip-chip method, it is unable to test whether the first chip 10′ is a known good die (KGD). In other words, if the first chip 10′ is not good in quality, it cannot be tested until the packaging process has been completed, thereby degrading the yield of a fabricated product and increasing the overall packaging costs. Accordingly, if it is able to test whether the chip 10′ is a known good die (KGD) before stacking the second chip 14′ on the first chip 10′, the possible waste of costs on the second chip 14′ and subsequent fabrication processes can be avoided, the yield of the fabricated product can be improved, and the packaging costs can be reduced.

During the underfilling process using the resin material 13′, the bond pads 120′ on the substrate 12′ may easily be contaminated by the resin material 13′. If the bond pads 120′ are contaminated, the gold wires 15′ cannot be successfully bonded to the bond pads 120′, such that the electrical connection between the second chip 14′ and the substrate 12′ is incomplete. This similarly degrades the yield of the fabricated product and increases the overall packaging costs.

As previously mentioned, due to the small pitch between the adjacent solder bumps 11′, the solder bump 11′ may easily become bridged during a process of reflowing the solder bumps 11′ to the substrate 12′. The bridging effect of the solder bumps 11′ leads to short circuit between the first chip 10′ and the substrate 12′, which further degrades the yield of the fabricated product and increases the overall packaging costs.

As the semiconductor package 1′ incorporates both the first chip 10′ and the second chip 14′, heat generated during operation of the chips is greatly increased. If the heat cannot be effectively dissipated, the lifetime of the semiconductor package would be reduced. Accordingly, U.S. Pat. No. 6,472,471 discloses a package with a metal heat spreader being interposed between two chips. However, due to significant mismatch in coefficient of thermal expansion (CTE) between the chips and the heat spreader, the heat spreader interposed between the two chips causes the chips to crack by thermal stress generated in response to the CTE mismatch. Therefore, this patented technology cannot effectively solve the heat dissipation problem.

### SUMMARY OF THE INVENTION

In light of the above prior-art drawbacks, a primary objective of the present invention is to provide a semiconductor device having a flip-chip package and a method for fabricating the same, so as to improve the yield of a fabricated product and reduce the overall packaging costs.

Another objective of the present invention is to provide a semiconductor device having a flip-chip package and a method for fabricating the same, which can reduce the overall packaging costs without having to use a build-up substrate.

Still another objective of the present invention is to provide a semiconductor device having a flip-chip package and a method for fabricating the same, which can test whether a first chip is a known good die (KGD) before performing subsequent fabrication processes, so as to improve the yield of a fabricated product.

A further objective of the present invention is to provide a semiconductor device having a flip-chip package and a method for fabricating the same, which can eliminate contamination to a bond pad on a chip carrier so as to improve the yield of a fabricated product.

A further objective of the present invention is to provide a semiconductor device having a flip-chip package and a method for fabricating the same, so as to improve the heat dissipating efficiency.

In accordance with the above and other objectives, the present invention proposes a semiconductor device, which comprises a flip-chip package, wherein the flip-chip package comprises a first chip electrically connected to a build-up substrate in a flip-chip manner, and a first encapsulant formed on the build-up substrate for encapsulating the first chip; a carrier for mounting and electrically connecting the flip-chip package; at least a second chip mounted on the flip-chip package and electrically connected to the carrier by a plurality of bonding wires; and a second encapsulant formed on the carrier for encapsulating the flip-chip package and the second chip.

As the flip-chip package is a complete package, it can be tested once its packaging process has been completed, such that subsequent fabrication processes can be performed after determining whether the first chip incorporated in the flip-chip package is a known good die (KGD), thereby improving the yield of a fabricated product and reducing the packaging costs. The flip-chip package is electrically connected to the carrier by a plurality of solder balls commonly used in a general BGA semiconductor package. As the carrier can be a general subtractive-type laminated substrate instead of an expensive build-up substrate, the present invention using a small build-up substrate and a large subtractive-type substrate still has lower packaging costs than the prior-art technology using a large build-up substrate. As a pitch between the adjacent solder balls is much larger than a pitch between adjacent solder bumps, the solder balls would not easily become bridged during a reflow process of the solder balls, thereby improving the yield of the fabricated product. There is no need to perform an underfilling process to fill a gap between the flip-chip package and the carrier as the flip-chip package is electrically connected to the carrier by the solder balls, such that bond pads formed on the carrier for bonding the bonding wires would not be contaminated, thereby further improving the yield of the fabricated product.

The present invention also proposes a method for fabricating the above semiconductor device, which comprises the steps of forming a flip-chip package by preparing a build-up substrate, electrically connecting a first chip to the build-up substrate in a flip-chip manner and forming an encapsulant for encapsulating the first chip; allowing the flip-chip package to be tested before being mounted and electrically connected to a carrier; mounting at least a second chip on the flip-chip package and electrically connecting the second chip to the carrier via a plurality of bonding wires; and forming a second encapsulant on the carrier for encapsulating the flip-chip package, the second chip and the bonding wires.

In another preferred embodiment of the present invention, an inactive surface of the first chip is exposed from the first encapsulant of the flip-chip package, such that the second chip can be directly attached to the inactive surface of the first chip to reduce an overall thickness of the semiconductor device in the present invention.

In still another preferred embodiment of the present invention, the inactive surface of the first chip is exposed from the first encapsulant of the flip-chip package, such that a heat spreader can be provided on the flip-chip package and directly attached to the inactive surface of the first chip, and the second chip is directly mounted on the heat spreader, such that heat generated by the first chip and the second chip can be directly transmitted to the heat spreader, so as to improve heat dissipating efficiency of the semiconductor device in the present invention.

In a further preferred embodiment of the present invention, the inactive surface of the first chip is exposed from the first encapsulant of the flip-chip package, such that the first chip and the second chip can be directly in contact with the heat spreader. Moreover, the second chip can be grounded to the heat spreader by a plurality of first ground wires and further grounded to the carrier by a plurality of second ground wires, such that the heat spreader serves as a ground plane to improve electrical performance of the semiconductor device in the present invention.

In a further preferred embodiment of the present invention, two horizontally arranged second chips or two vertically stacked second chips are mounted on the flip-chip package. The two second chips are electrically interconnected by a plurality of bonding wires to further improve the overall functionality of the semiconductor device in the present invention.

In a further preferred embodiment of the present invention, the flip-chip package is mounted on the carrier in a manner that external connection contacts of the build-up substrate face upwardly, such that the second chip is directly mounted on the build-up substrate of the flip-chip package. The second chip is electrically connected to the build-up substrate by a plurality of second bonding wires, and the build-up substrate is electrically connected to the carrier by a plurality of first bonding wires.

In a further preferred embodiment of the present invention, the flip-chip package is mounted on the carrier in a manner that external connection contacts of the build-up substrate face upwardly, and the inactive surface of the first chip is exposed from the first encapsulant of the flip-chip package, such that the exposed inactive surface of the first chip can be directly mounted on the carrier, so as to effectively reduce the overall thickness of the fabricated product.

### BRIEF DESCRIPTION OF THE DRAWINGS

The present invention can be more fully understood by reading the following detailed description of the preferred embodiments, with reference made to the accompanying drawings, wherein:

FIGS. 1A to 1E are cross-sectional views showing a semiconductor device having a flip-chip package and a method for fabricating the same according to a first preferred embodiment of the present invention;

FIG. 2 is a cross-sectional view showing a semiconductor device having a flip-chip package according to a second preferred embodiment of the present invention;

FIG. 3 is a cross-sectional view showing a semiconductor device having a flip-chip package according to a third preferred embodiment of the present invention;

FIG. 4 is a cross-sectional view showing a semiconductor device having a flip-chip package according to a fourth preferred embodiment of the present invention;

FIG. 5 is a cross-sectional view showing a semiconductor device having a flip-chip package according to a fifth preferred embodiment of the present invention;

FIG. 6 is a cross-sectional view showing a semiconductor device having a flip-chip package according to a sixth preferred embodiment of the present invention;

FIG. 7 is a cross-sectional view showing a semiconductor device having a flip-chip package according to a seventh preferred embodiment of the present invention;

FIG. 8 is a cross-sectional view showing a semiconductor device having a flip-chip package according to an eighth preferred embodiment of the present invention;

FIG. 9 is a cross-sectional view showing a semiconductor device having a flip-chip package according to a ninth preferred embodiment of the present invention; and

FIG. 10 (PRIOR ART) is a cross-sectional view showing a conventional semiconductor package having multiple stacked chips.

### DETAILED DESCRIPTION OF THE PREFERRED EMBODIMENTS

A semiconductor device having a flip-chip package proposed in present invention is described with the following preferred embodiments, such that a person skilled in the pertinent art can easily understand the present invention. The present invention may also be implemented and applied according to other embodiments, which can be modified based on different application requirements without departing from the spirit of the invention. Further, a method for fabricating the semiconductor device having a flip-chip package proposed in the present invention is described for a single device in the following embodiments. However, it is understood that the semiconductor device can be fabricated in a batch type manner.

### First Preferred Embodiment

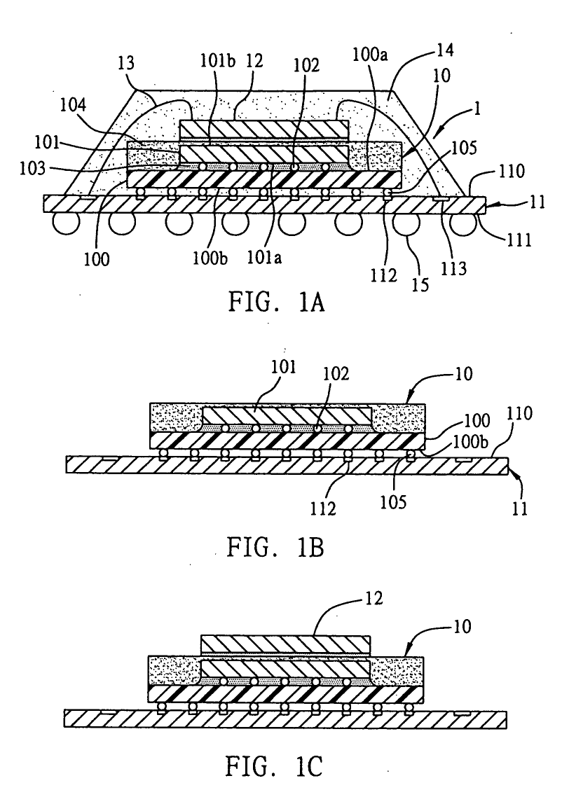

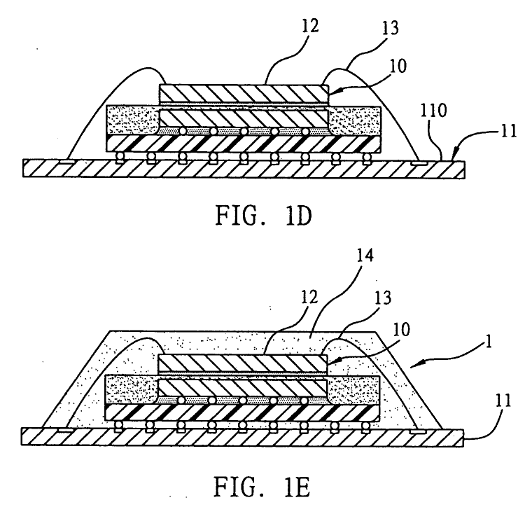

FIG. 1A is a cross-sectional view showing a semiconductor device having a flip-chip package according to a first preferred embodiment of the present invention. FIGS. 1B to 1E are cross-sectional views showing a method for fabricating the semiconductor device shown in FIG. 1A.

As shown in FIG. 1A, the semiconductor device 1 of the first preferred embodiment comprises a flip-chip package 10; a carrier 11 for mounting and electrically connecting the flip-chip package 10; a second chip 12 mounted on the flip-chip package 10; a plurality of gold wires 13 for electrically connecting the second chip 12 to the carrier 11; a second encapsulant 14 formed on the carrier 11 for encapsulating the flip-chip package 10, the second chip 12 and the gold wires 13; and a plurality of array-arranged solder balls 15 implanted on the carrier 11.

The flip-chip package 10 comprises a build-up substrate 100 having a first surface 100a and a corresponding second surface 100b; a first chip 101 having an active surface 101a and a corresponding inactive surface 101b; a plurality of array-arranged solder bumps 102 bonded to the active surface 101a of the first chip 101, such that the active surface 101a of the first chip 101 is electrically connected to the first surface 100a of the build-up substrate 100 by the solder bumps 102; a resin material 103 filled in a gap between the first chip 101 and the build-up substrate 100 by an underfilling process for encapsulating the solder bumps 102; a first encapsulant 104 formed on the build-up substrate 100 for encapsulating the first chip 101; and a plurality of solder balls 105 implanted on the second surface 100b of the build-up substrate 100.

The flip-chip package 10 has similar structure and fabrication method to a conventional flip-chip package, which are thus not to be further described herein. Apart from filling the resin material 101 in the gap between the first chip 101 and the build-up substrate 100, the gap and the solder bumps 102 may alternatively be directly filled and encapsulated by the first encapsulant 104 formed on the build-up substrate 100 for encapsulating the first chip 101. The flip-chip package 10 is preferably a chip size package (CSP), wherein the flip-chip package 10 needs to have a size only slightly larger than that of the chip, such that the size of the build-up substrate 100 and fabrication costs are reduced.

The flip-chip package 10 is a completely fabricated package and is readily subjected to a test to determine whether the encapsulated first chip 101 is a known good die (KGD). After the quality of the first chip 101 is confirmed, the flip-chip package 10 can be mounted to the carrier 11 by the solder balls 105.

The carrier 11 has a top surface 110 and a corresponding bottom surface 111. A plurality of ball pads 112 corresponding to the solder balls 105 are formed on a central area of the top surface 110, and a plurality of bond pads 113 are formed on the top surface 110 at an area free of forming the ball pads 112. The flip-chip package 10 is mounted and electrically connected to the carrier 11 by bonding the solder balls 105 of the flip-chip package 10 to the ball pads 112 of the carrier 11. As a pitch between the adjacent solder balls 105 of the flip-chip package 10 generally ranges from 500 to 800 μm, a conventional subtractive-type substrate may serve as the carrier 11, without having to use a build-up substrate having a pitch between adjacent bump pads ranging from 150 to 250 μm. The sum of costs of the small build-up substrate 100 and a large subtractive-type substrate as the carrier 11 used in the semiconductor device 1 in the present invention is lower than the cost of a large build-up substrate used in the conventional semiconductor package in the prior art as the large build-up substrate is very expensive, such that packaging costs in the present invention are reduced.

After mounting the second chip 12 on the flip-chip package 10, the gold wires 13 are bonded to the second chip 12 and the bond pads 113 of the carrier 11 so as to electrically connect the second chip 12 to the carrier 11 via the gold wires 13.

FIGS. 1B to 1E showing the steps of a method for fabricating the semiconductor device 1 according to the first preferred embodiment of the present invention.

Referring to FIG. 1B, a completely fabricated flip-chip package 10 (as shown in FIG. 1A) is mounted on a top surface 110 of a carrier 11, and is electrically connected to the carrier 11 by a plurality of solder balls 105 mounted on a second surface 100b of a build-up substrate 100 of the flip-chip package 10. Thus, a first chip 101 encapsulated in the flip-chip package 10 is electrically connected to the carrier 11 through solder bumps 102, the build-up substrate 100 and the solder balls 105. It should be noted that the flip-chip package 10 before being mounted on the carrier 11 is subjected to a test to confirm the quality of the first chip 101, such that a waste of subsequent fabrication processes is avoided and the yield of a fabricated product is improved. As a pitch between the adjacent solder balls 105 of the flip-chip package 10 generally ranges from 500 to 800 μm, the solder balls 105 would not become bridged when being bonded to the carrier 11. Accordingly, a pitch between adjacent ball pads 112 formed on the carrier 11 for bonding the solder balls 105 is also large, and a subtractive-type substrate such as a conventional dual-layer subtractive-type substrate can be used as the carrier 11.

Referring to FIG. 1C, a second chip 12 is mounted on the flip-chip package 10. The attachment between the second chip 12 and the flip-chip package 10 can be achieved by any appropriate method and adhesive material, which are known in the art and thus not to be further described herein.

Referring to FIG. 1D, a wire-bonding process is performed to electrically connect the second chip 12 to the carrier 11 via a plurality of gold wires 13. As the flip-chip package 10 is mounted to the carrier 11 by the solder balls 105, no underfilling process is required to fill a gap between the flip-chip package 10 and the carrier 11. Thus, bond pads 113 formed on the top surface 110 of the carrier 11 for bonding the gold wires 13 are free of being contaminated, and the gold wires 13 can be well bonded to the bond pads 113, thereby improving the yield of the fabricated product.

Referring to FIG. 1E, after completing the electrical connection between the second chip 12 and the carrier 11, a molding process is performed to form a second encapsulant 14 on the carrier 11 for encapsulating the flip-chip package 10, the second chip 12 and the gold wires 13. The molding process and a resin material for forming the second encapsulant 14 are both known in the art and thus not to be further described herein.

Finally, a conventional ball-implanting process is performed to implant a plurality of array-arranged solder balls 15 on a bottom surface 111 of the carrier 11.

This completes the method for fabricating the semiconductor device 1 shown in FIG. 1A.

### Second Preferred Embodiment

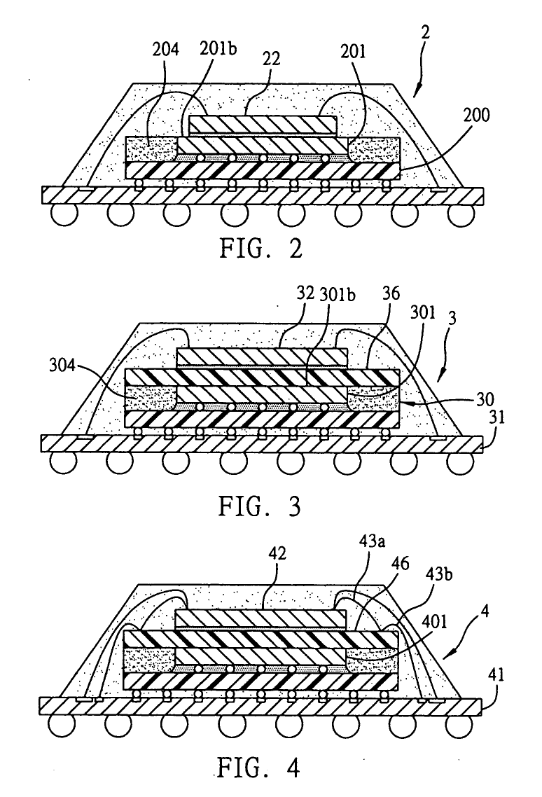

FIG. 2 is a cross-sectional view showing a semiconductor device having a flip-chip package according to a second preferred embodiment of the present invention.

Referring to FIG. 2, the semiconductor device 2 having a flip-chip package in the second preferred embodiment is structurally similar to that in the first preferred embodiment, with the difference in that for the semiconductor device 2, an inactive surface 201b of a first chip 201 encapsulated in a flip-chip package 20 is exposed from a first encapsulant 204 formed on a build-up substrate 200 for mounting the first chip 201. After the flip-chip package 20 is mounted on a carrier 21, a second chip 22 can be directly attached to the inactive surface 201b of the first chip 201. Therefore, an overall thickness of the fabricated semiconductor device 2 is smaller than that of the semiconductor device 1 in the first preferred embodiment.

Besides, in order to further reduce the thickness of the flip-chip package 20, a conventional grinder can be used to grind the top of the exposed inactive surface 201b of the flip-chip package 20 after completing a packaging process of the flip-chip package 20, so as to reduce the predetermined thicknesses of the first encapsulant 204 and the first chip 201.

### Third Preferred Embodiment

FIG. 3 is a cross-sectional view showing a semiconductor device having a flip-chip package according to a third preferred embodiment of the present invention.

Referring to FIG. 3, the semiconductor device 3 having a flip-chip package in the third preferred embodiment is structurally similar to that in the second preferred embodiment, with the difference in that for the semiconductor device 3, after a flip-chip package 30 is fabricated, a heat spreader 36 made of a metal material is mounted on the flip-chip package 30, such that an inactive surface 301b of a first chip 301 exposed from a first encapsulant 304 in the flip-chip package 30 can be directly attached to the heat spreader 36. After the flip-chip package 30 mounted with the heat spreader 36 is electrically connected to a carrier 31 by a plurality of solder balls 305, a second chip 32 is directly attached to the heat spreader 36. Therefore, the first chip 301 and the second chip 32 of the semiconductor device 3 are both directly attached to the heat spreader 36, and heat generated by the first chip 301 and the second chip 32 can be directly transmitted to the heat spreader 36, so as to improve heat dissipating efficiency of the semiconductor device 3.

### Fourth Preferred Embodiment

FIG. 4 is a cross-sectional view showing a semiconductor device having a flip-chip package according to a fourth preferred embodiment of the present invention.

Referring to FIG. 4, the semiconductor device 4 having a flip-chip package in the fourth preferred embodiment is structurally similar to that in the third preferred embodiment, with the difference in that for the semiconductor device 4, besides a heat dissipating medium, a heat spreader 46 interposed between a first chip 401 and a second chip 42 can also serve as a ground plane for the first chip 401 and the second chip 42. In order for the heat spreader 46 to provide a grounding effect, a plurality of first ground gold wires 43a are bonded to the second chip 42 and the heat spreader 46 so as to ground the second chip 42 to the heat spreader 46, and a plurality of second ground gold wires 43b are bonded to the heat spreader 46 and a carrier 41, such that the first chip 401 and the second chip 42 can both be grounded to the carrier 41 via the heat spreader 46, thereby improving the electrical performance of the semiconductor device 4.

### Fifth Preferred Embodiment

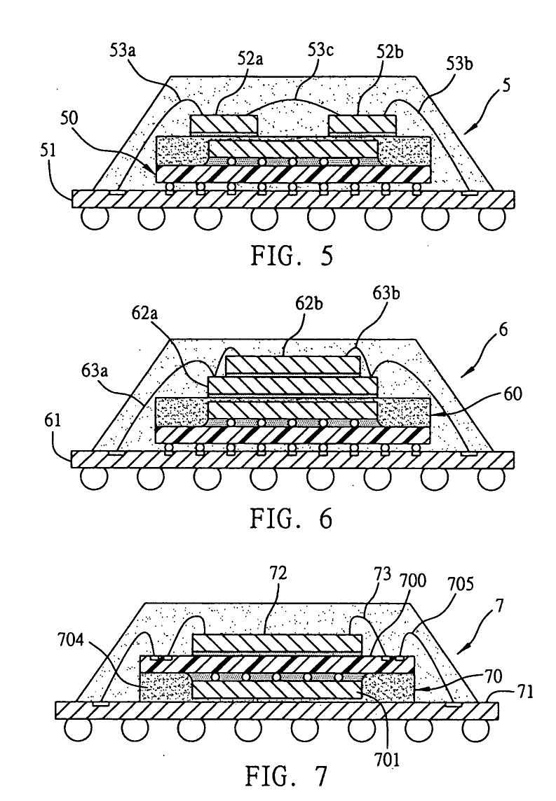

FIG. 5 is a cross-sectional view showing a semiconductor device having a flip-chip package according to a fifth preferred embodiment of the present invention.

Referring to FIG. 5, the semiconductor device 5 having a flip-chip package in the fifth preferred embodiment is structurally similar to that in the first preferred embodiment, with the difference in that for the semiconductor device 5, two identical second chips 52a, 52b are horizontally mounted on a flip-chip package 50 and spaced apart from each other. The two second chips 52a, 52b are electrically connected to a carrier 51 by a plurality of gold wires 53a, 53b, respectively. In order to further improve the electrical performance, the two second chips 52a, 52b are electrically connected to each other by a plurality of gold wires 53c. This allows the semiconductor device 5 to incorporate more chips therein to satisfy requirements of different advanced electronic products.

### Sixth Preferred Embodiment

FIG. 6 is a cross-sectional view showing a semiconductor device having a flip-chip package according to a sixth preferred embodiment of the present invention.

Referring to FIG. 6, the semiconductor device 6 having a flip-chip package in the sixth preferred embodiment is structurally similar to that in the fifth preferred embodiment, with the difference in that for the semiconductor device 6, two second chips 62a, 62b are vertically stacked on a flip-chip package 60. The second chip 62b is electrically connected to the second chip 62a by a plurality of gold wires 63b, and the second chip 62a is electrically connected to a carrier 61 by a plurality of gold wires 63a, such that the two second chips 62a, 62b are both electrically connected to the carrier 61.

### Seventh Preferred Embodiment

FIG. 7 is a cross-sectional view showing a semiconductor device having a flip-chip package according to a seventh preferred embodiment of the present invention.

Referring to FIG. 7, the semiconductor device 7 having a flip-chip package in the seventh preferred embodiment is structurally similar to that in the first preferred embodiment, with the difference in that for the semiconductor device 7, a flip-chip package 70 is mounted on a carrier 71 in a manner that external connection contacts of a build-up substrate 700 of the flip-chip package 70 face upwardly and a first encapsulant 704 for encapsulating a first chip 701 of the flip-chip package 70 is attached to the carrier 71. A second chip 72 is mounted on the build-up substrate 700 of the flip-chip package 70 and is electrically connected to the build-up substrate 700 by a plurality of gold wires 73. The build-up substrate 700 is electrically connected to the carrier 71 by a plurality of gold wires 705. Therefore, the first chip 701 and the second chip 72 are both electrically connected to the carrier 71.

### Eighth Preferred Embodiment

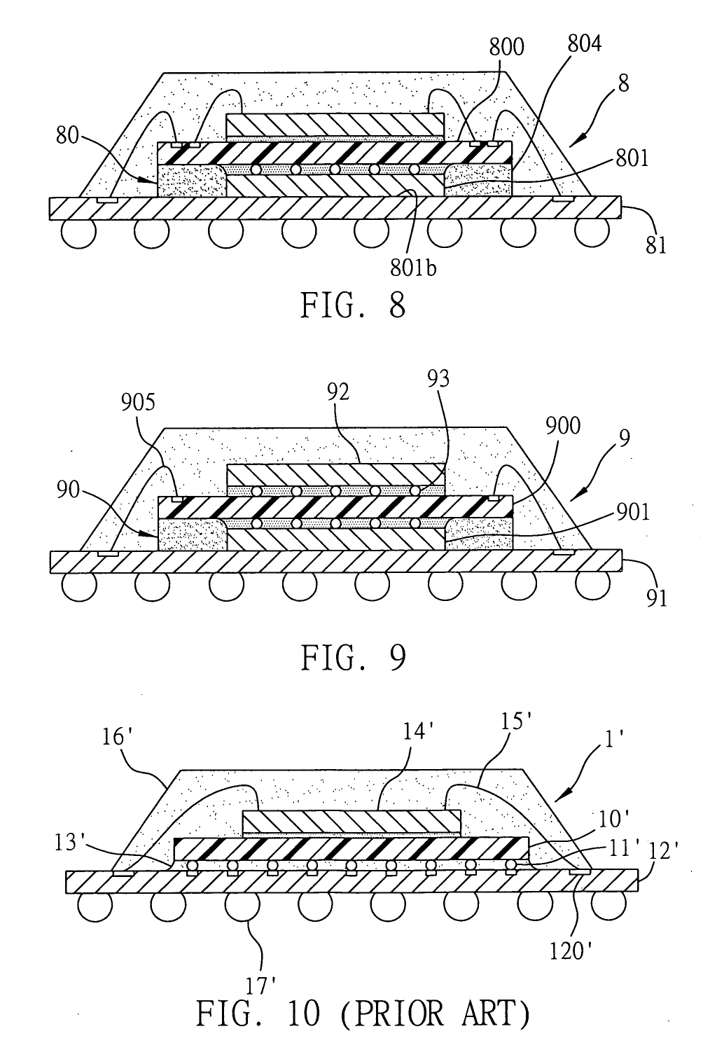

FIG. 8 is a cross-sectional view showing a semiconductor device having a flip-chip package according to an eighth preferred embodiment of the present invention.

Referring to FIG. 8, the semiconductor device 8 having a flip-chip package in the eighth preferred embodiment is structurally similar to that in the seventh preferred embodiment, with the difference in that for the semiconductor device 8, an inactive surface 801b of a first chip 801 encapsulated in a flip-chip package 80 is exposed from a first encapsulant 804 of the flip-chip package 80. When the flip-chip package 80 is mounted on a carrier 81, the inactive surface 801b of the first chip 801 is directly in contact with the carrier 81. Such arrangement with the exposed inactive surface 801b of the first chip 801 can reduce an overall thickness of the semiconductor device 8 and improve heat dissipating efficiency.

### Ninth Preferred Embodiment

FIG. 9 is a cross-sectional view showing a semiconductor device having a flip-chip package according to a ninth preferred embodiment of the present invention.

Referring to FIG. 9, the semiconductor device 9 having a flip-chip package in the ninth preferred embodiment is structurally similar to that in the eighth preferred embodiment, with the difference in that for the semiconductor device 9, a second chip 92 is electrically connected to a build-up substrate 900 of a flip-chip package 90 by a plurality of solder bumps 93, such that a first chip 901 of the flip-chip package 90 and the second chip 92 are both electrically connected to the build-up substrate 900 by a flip-chip method. The build-up substrate 900 is electrically connected to a carrier 91 by a plurality of gold wires 905, such that the first chip 901 and the second chip 92 are both electrically connected to the carrier 91.

The present invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor device having a flip-chip package, comprising:
a carrier having a top surface and a corresponding bottom surface;
a flip-chip package mounted on the top surface of the carrier, and electrically connected to the carrier by a plurality of solder balls;
at least a second chip mounted on the flip-chip package;
a plurality of bonding wires for electrically connecting the second chip to the carrier; and
a second encapsulant formed on the top surface of the carrier, for encapsulating the flip-chip package, the second chip and the bonding wires.

2. The semiconductor device of claim 1, wherein the flip-chip package comprises a build-up substrate having a first surface and a corresponding second surface, a first chip, a plurality of solder bumps for electrically connecting the first chip to the first surface of the build-up substrate, a first encapsulant formed on the first surface of the build-up substrate for encapsulating the first chip, and the plurality of solder balls implanted on the second surface of the build-up substrate.

3. The semiconductor device of claim 1, further comprising a plurality of solder balls implanted on the bottom surface of the carrier.

4. The semiconductor device of claim 2, wherein the first chip is completely encapsulated by the first encapsulant.

5. The semiconductor device of claim 2, wherein an inactive surface of the first chip is exposed from the first encapsulant, such that the second chip is directly attached to the inactive surface of the first chip.

6. The semiconductor device of claim 2, wherein an inactive surface of the first chip is exposed from the first encapsulant and the semiconductor device further comprises a heat spreader mounted on the flip-chip package, such that the first chip and the second chip are both directly attached to the heat spreader.

7. The semiconductor device of claim 6, wherein the second chip is grounded to the heat spreader by a plurality of second ground wires and the heat spreader is grounded to the carrier by a plurality of first ground wires.

8. The semiconductor device of claim 1, wherein there are two second chips horizontally mounted on the flip-chip package and spaced part from each other.

9. The semiconductor device of claim 8, further comprising a plurality of bonding wires for electrically connecting the two second chips to each other.

10. The semiconductor device of claim 1, wherein there are two second chips vertically stacked on the flip-chip package and electrically connected to each other.

11. The semiconductor device of claim 1, wherein the carrier is a subtractive-type laminated substrate.

12. The semiconductor device of claim 2, wherein the flip-chip package before being mounted on the carrier is tested and is confirmed with quality of the first chip therein.

13. A method for fabricating a semiconductor device having a flip-chip package, comprising the steps of:
mounting a flip-chip package on a carrier, the carrier having a top surface and a corresponding bottom surface, wherein the flip-chip package comprises:
a build-up substrate having a first surface and a corresponding second surface, a first chip, a plurality of solder bumps for electrically connecting the first chip to the first surface of the build-up substrate, a first encapsulant formed on the first surface of the build-up substrate for encapsulating the first chip, and a plurality of solder balls implanted on the second surface of the build-up substrate, wherein the flip-chip package is electrically connected to the top surface of the carrier by the solder balls;
mounting at least a second chip on the flip-chip package;
electrically connecting the second chip to the carrier via a plurality of bonding wires; and
forming a second encapsulant on the top surface of the carrier for encapsulating the flip-chip package, the second chip and the bonding wires.

14. The method of claim 13, further comprising a step of testing the flip-chip package before mounting the flip-chip package on the carrier.

15. The method of claim 13, wherein the carrier is a subtractive-type laminated substrate.

16. The method of claim 13, further comprising a step of implanting a plurality of solder balls on the bottom surface of the carrier after forming the second encapsulant on the carrier.

17. A method for fabricating a semiconductor device having a flip-chip package, comprising the steps of:
mounting a flip-chip package on a carrier, the carrier having a top surface and a corresponding bottom surface, wherein the flip-chip package comprises:
a build-up substrate having a first surface and a corresponding second surface, a first chip, a plurality of solder bumps for electrically connecting the first chip to the first surface of the build-up substrate, a first encapsulant formed on the first surface of the build-up substrate for partially encapsulating the first chip wherein an inactive surface of the first chip is exposed from the first encapsulant, and a plurality of solder balls implanted on the second surface of the build-up substrate, wherein the flip-chip package is electrically connected to the top surface of the carrier by the solder balls;
attaching a heat spreader to the flip-chip package, wherein the inactive surface of the first chip is directly in contacted with the heat spreader;
attaching at least a second chip to the heat spreader, wherein the heat spreader is interposed between the first chip and the second chip;
electrically connecting the second chip to the carrier via a plurality of bonding wires; and
forming a second encapsulant on the top surface of the carrier for encapsulating the flip-chip package, the second chip and the bonding wires.

18. The method of claim 17, further comprising a step of testing the flip-chip package before mounting the flip-chip package on the carrier.

19. The method of claim 17, wherein the carrier is a subtractive-type laminated substrate.

20. The method of claim 17, further comprising a step of implanting a plurality of solder balls on the bottom surface of the carrier after forming the second encapsulant on the carrier.

21. The method of claim 17, further comprising a step of bonding a plurality of ground wires to the second chip and the heat spreader and to the heat spreader and the carrier respectively when electrically connecting the second chip to the carrier via the bonding wires, such that the second chip is grounded to the carrier via the heat spreader.

22. A semiconductor device having a flip-chip package, comprising:
a carrier having a top surface and a corresponding bottom surface;
a flip-chip package mounted on the top surface of the carrier, the flip-chip package comprising a build-up substrate, wherein external connection contacts of the build-up substrate face upwardly;
at least a second chip mounted on the build-up substrate of the flip-chip package;
a plurality of conductive elements for electrically connecting the second chip to the flip-chip package and electrically connecting the flip-chip package to the carrier respectively; and
a second encapsulant formed on the top surface of the carrier, for encapsulating the flip-chip package, the second chip and the conductive elements.

23. The semiconductor device of claim 22, wherein the flip-chip package comprises the build-up substrate having a first surface and a corresponding second surface, a first chip, a plurality of solder bumps for electrically connecting the first chip to the first surface of the build-up substrate, and a first encapsulant formed on the first surface of the build-up substrate for encapsulating the first chip.

24. The semiconductor device of claim 22, further comprising a plurality of solder balls implanted on the bottom surface of the carrier.

25. The semiconductor device of claim 23, wherein the first chip is completely encapsulated by the first encapsulant.

26. The semiconductor device of claim 23, wherein an inactive surface of the first chip is exposed from the first encapsulant and is directly attached to the top surface of the carrier.

27. The semiconductor device of claim 22, wherein the carrier is a subtractive-type laminated substrate.

28. The semiconductor device of claim 23, wherein the flip-chip package before being mounted on the carrier is tested and is confirmed with quality of the first chip therein.

29. The semiconductor device of claim 22, wherein the conductive elements are bonding wires.

30. The semiconductor device of 22, wherein the conductive elements include bonding wires and solder bumps, such that the second chip is electrically connected to the build-up substrate of the flip-chip package by the solder bumps, and the build-up substrate of the flip-chip package is electrically connected to the carrier by the bonding wires.
